(19) United States
(12) Patent Application Publication
(10) Pub. No.: US 2017/0249210 A1
(43) Pub. Date: Aug. 31, 2017

(54) MEMORY DEVICE AND MEMORY SYSTEM

(71) Applicant: KABUSHIKI KAISHA TOSHIBA, Tokyo (JP)

(72) Inventor: Hisato OYAMATSU, Seoul (KR)

(73) Assignee: KABUSHIKI KAISHA TOSHIBA, Tokyo (JP)

(21) Appl. No.: 15/265,717

(22) Filed: Sep. 14, 2016

Related U.S. Application Data
(60) Provisional application No. 62/301,119, filed on Feb. 29, 2016.

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

According to an embodiment, a memory device includes a plurality of decoders each configured to (i) correct an error and output a corrected read data item if a read data item from a memory circuit corresponding to the decoder contains one error, and (ii) output the read data item if no error is detected in the read data item; and a majority circuit configured to output a read data item which is the same as one of the read data items of the most read data items output from the plurality of decoders.

### CROSS-REFERENCE TO RELATED APPLICATIONS

This application claims the benefit of U.S. Provisional Application No. 62/301,119, filed Feb. 29, 2016, the entire contents of which are incorporated herein by reference.

### FIELD

Embodiments described herein relate generally to a memory device and a memory system.

### BACKGROUND

A random access memory (RAM) is in wide use. In general, the RAM requires a high-speed operation.

### BRIEF DESCRIPTION OF THE DRAWINGS

FIG. 1 is a schematic diagram illustrating the symbols of an approximate model of an error correction method according to an embodiment.

FIG. 2 is a schematic diagram illustrating two data sets of an approximate model of an error correction method according to an embodiment.

FIG. 3 is a schematic diagram illustrating three data sets of an approximate model of an error correction method according to an embodiment.

FIG. 4 is a schematic diagram illustrating four data sets of an approximate model of an error correction method according to an embodiment.

FIG. 5 is a schematic diagram illustrating how the number of data sets and error correction capability are related in an approximate model of an error correction method according to an embodiment.

FIG. 6 is a schematic diagram illustrating the symbols of a practical model of an error correction method according to an embodiment.

FIG. 7 is a schematic diagram illustrating two data sets of a practical model of an error correction method according to an embodiment.

FIG. 8 is a schematic diagram illustrating three data sets of a practical model of an error correction method according to an embodiment.

FIG. 9 is a schematic diagram illustrating four data sets of a practical model of an error correction method according to an embodiment.

FIG. 10 is a schematic diagram illustrating four data sets of a practical model of an error correction method according to an embodiment.

FIG. 11 is a schematic diagram illustrating four data sets of a practical model of an error correction method according to an embodiment.

FIG. 12 is a schematic diagram illustrating how the number of data sets and error correction capability are related in a practical model of an error correction method according to an embodiment.

FIG. 13 is a schematic diagram illustrating function blocks of a memory device according to a embodiment.

FIG. 14 is a schematic diagram illustrating an example of an MTJ element of the first embodiment.

FIG. 15 is a schematic diagram illustrating function blocks of an ECC circuit according to the first embodiment.

FIG. 16 is a schematic diagram illustrating a parity bit and check matrix principle used in the first embodiment.

FIG. 17 is a flowchart illustrating an operation performed in the first embodiment.

FIG. 18 is a schematic diagram illustrating function blocks of another example of a memory device and a memory controller according to the first embodiment.

FIG. 19 is a schematic diagram illustrating function blocks of an ECC circuit according to a second embodiment.

FIG. 20 is a flowchart illustrating an operation performed in the second embodiment.

### DETAILED DESCRIPTION

According to an embodiment, a memory device includes a plurality of decoders each configured to (i) correct an error and output a corrected read data item if a read data item from a memory circuit corresponding to the decoder contains one error, and (ii) output the read data item if no error is detected in the read data item; and a majority circuit configured to output a read data item which is the same as one of the read data items of the most read data items output from the plurality of decoders.

Before the embodiments are described with reference to the drawings, an error correction method according to an embodiment will be described. In the description below, structural elements having substantially the same functions and configurations will be denoted by the same reference symbols, and a repetitive description will be given only where necessary. The drawings are schematic. The descriptions of one embodiment are all applicable to the other embodiments, unless such application is excluded explicitly or obviously.

Each of the function blocks shown in the Figures can be implemented in the form of hardware, computer software or a combination of them. In order to clarify what are specifically meant by the function blocks, the function blocks will be explained below in terms of their functions. The functional blocks need not be those depicted in the Figures. For example, part of the functions of one exemplary function block may be implemented by another functional block. In addition, an exemplary function block may be divided into more specific function blocks. The embodiments are not limited by which function block a function is attained. The order of the steps of the control flows shown in the Figures can be changed unless such change is denied explicitly or obviously.

### <Outline of Error Correction Method According to Embodiment>

### [0-1] Outline

The error correction method according to an embodiment includes, for example, steps (a) to (c) described below. It should be note though that the error correction method according to the embodiment is not limited to a method including steps (a) to (c).

(a) storing data sets, including the same data and parity, in a plurality of memory areas in parallel;

(b) executing the same error correction for the data sets that are read from the memory areas in parallel; and

(c) selecting data having a minimum number of errors from a plurality of data obtained by the error correction.

According to the error correction method of the embodiment, the probability that all data sets stored in parallel are broken decreases significantly in accordance with an increase in the number of data sets (i.e., a parallel number). In other words, the probability that one of the data sets is in the normal state increases significantly in accordance with an increase in the parallel number.

Therefore, the error correction method of the embodiment enhances the error correction capability and reduces the calculation required for error correction.

Accordingly, fast data access is enabled by the memory device and memory system.

Next, approximate models and practical models of the error correction method of the embodiment will be described.

### [0-1-1] Approximate Models

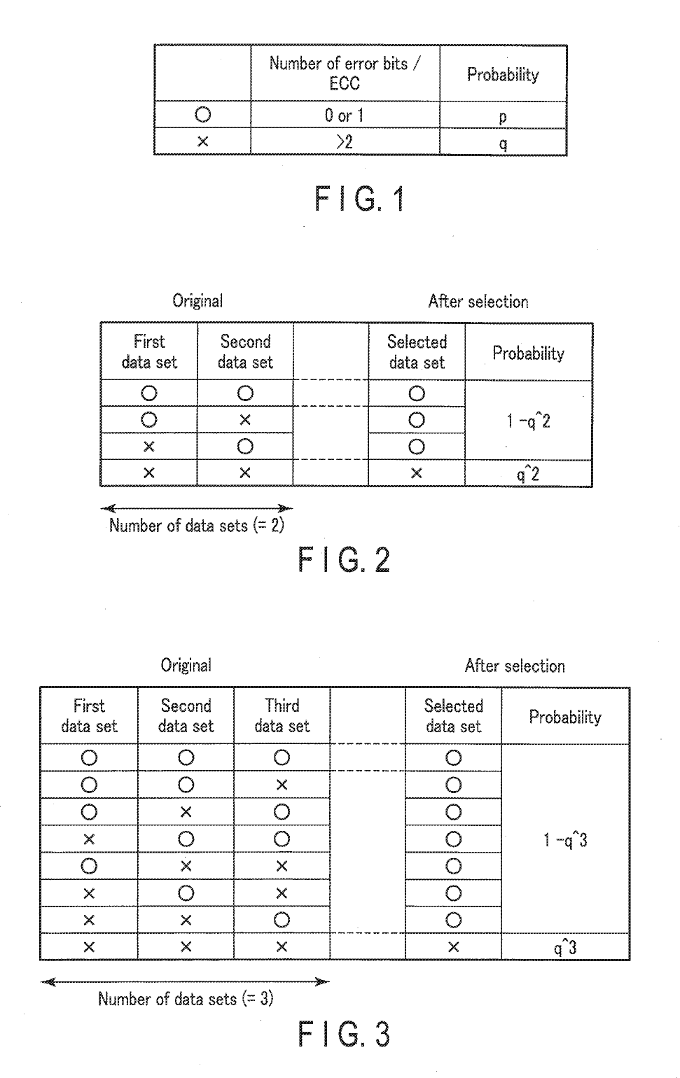

Approximate models of the error correction method of the embodiment will be described with reference to FIGS. 1 through 5. In connection with the description of the approximate models, the symbol “∘” represents a normal state where the number of error bits in one-time ECC processing is either 0 or 1 and the probability of occurrence of this state is p, as shown in FIG. 1. The symbol “x” represents an error occurrence state where the number of error bits in one-time ECC processing is 2 or more and the probability of occurrence of this state is q, as shown in FIG. 1 (provided that p+q=1, and q<p).

At the outset, an example of a case where a data set having a minimum number of errors is selected from between two data sets and the probability related to this example will be described with reference to FIG. 2. This example includes a first data set and a second data set, each of which assumes either state “∘” or state “x”. There are four combinations between the states of the first and second data sets (4=2̂2, where ̂ a symbol representing a power index). Of these four combinations, the combination wherein both the first and second data sets are in the error occurrence state “x” has a probability expressed by q̂2. The probability that at least one of the first and second data sets is in the normal state “∘” is expressed by 1−q̂2. In other words, where two data sets are used, the read processing fails with a probability of “q̂2” and succeeds with a probability of “1−q̂2”. Let us assume that the memory capacity is M bits, and that the number of data bits checked in one-time ECC processing is n bits. In this case, the number of times the ECC processing is performed for all data is (M/n) times. Therefore, the yield of the read processing that is performed for all data is (the probability of success)̂(number of times ECC processing is performed)=(1−q̂2)̂(M/n).

Where there is only one data set, the probability of the data set assuming error occurrence state “x” is “q”. The yield of the read processing for all data is (1−q)̂(M/n).

Therefore, where two data sets are used, the probability of failure of the read processing decreases from “q” (which is the probability of the case where one data set is used) to “q̂2”. In accordance with this, the yield of the read processing of the case where two data sets are used increases from “(1−q)̂(M/n)”to “(1−q̂2)̂(M/n)”. It should be noted that p+q=1 and q<1. Accordingly, q̂2<q, and 1−q<1−q̂2.

Next, an example of a case where a data set having a minimum number of errors is selected from among three data sets and the probability related to this example will be described with reference to FIG. 3. There are eight combinations between the states of the first, second and third data sets (8=2̂3). Where three data sets are used, the read processing fails with a probability of “q̂3” and succeeds with a probability of “1−q̂3”. The yield of the read processing for all data is (1−q̂3)̂(M/n).

Therefore, where three data sets are used, the probability of failure of the read processing decreases from “q” (which is the probability of the case where one data set is used) to “q̂3”. The yield of the read processing of the case where three data sets are used increases from “(1−q)̂(M/n)” to “(1−q̂3)̂(M/n)”.

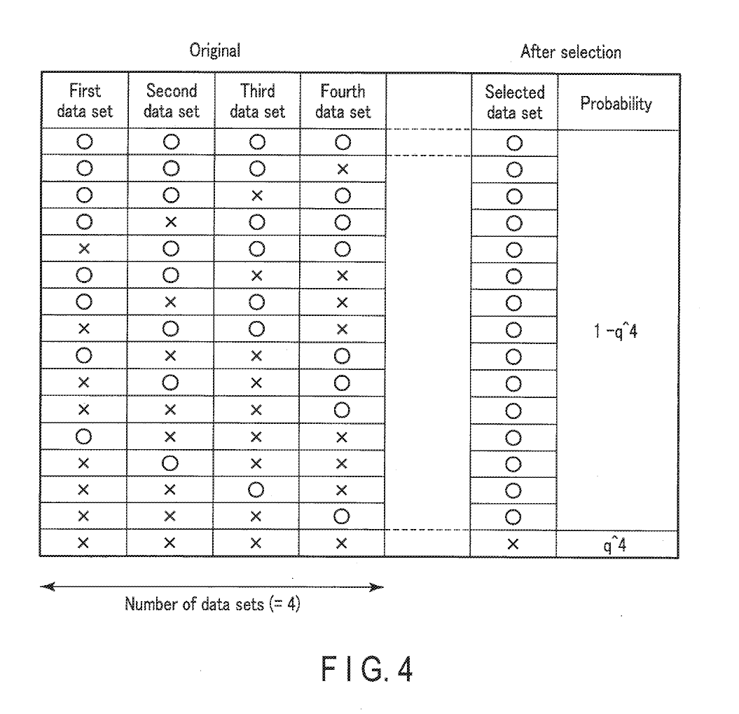

Next, an example of a case where a data set having a minimum number of errors is selected from among four data sets and the probability related to this example will be described with reference to FIG. 4. There are 16 combinations between the states of the first to fourth data sets (16=2̂4). Where four data sets are used, the read processing fails with a probability of “q̂4” and succeeds with a probability of “1−q̂4”. The yield of the read processing for all data is (1−q̂4)̂(M/n).

Therefore, where four data sets are used, the probability of failure of the read processing decreases from “q” (which is the probability of the case where one data set is used) to “q̂4”. The yield of the read processing of the case where four data sets are used increases from “(1−q)̂(M/n)” to “(1−q̂4)̂(M/n)”.

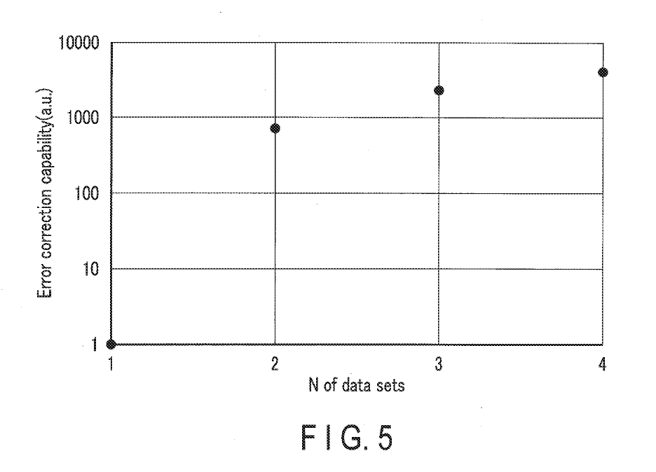

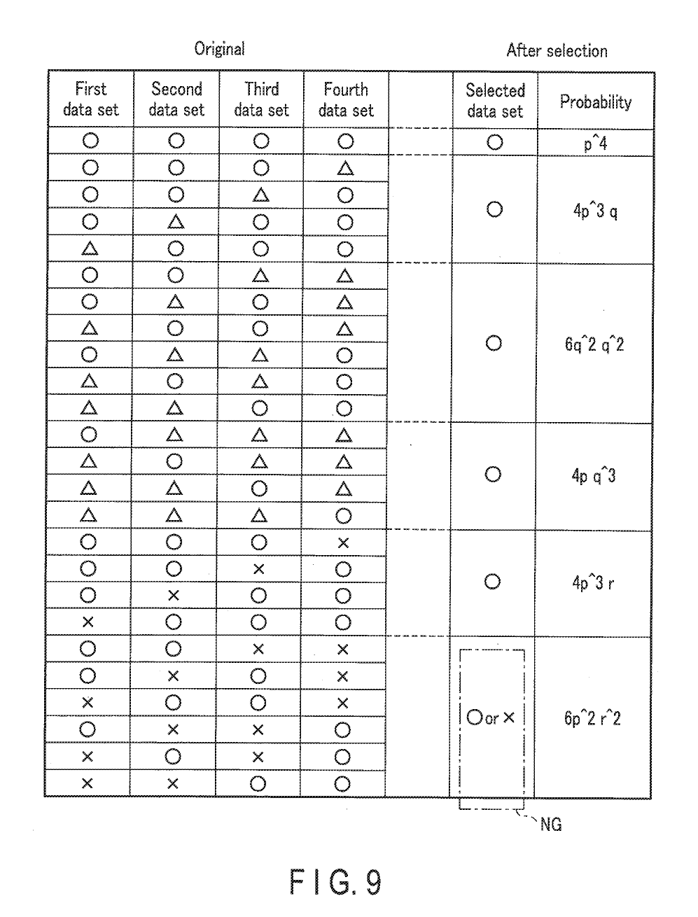

FIG. 5 illustrates how the number of data sets and error correction capability are related. It is assumed here that the ECC processing shown in FIGS. 1 to 4 uses Hamming codes, and that the error correction capability provides a reliability of 1,000 FIT for a memory capacity of 1 Gbit, using 64-bit data and an 8-bit parity. (“FIT” stands for Failure In Time and indicates an error occurrence rate for a time of 10⁹ hours [=10 million hours]). As shown in FIG. 9, the error correction capability increases in accordance with an increase in the number of data sets. Where two data sets are used, the error correction capability increases by 700 times or more. Where three data sets are used, the error correction capability increases by 2,000 times or more. Where four data sets are used, the error correction capability increases by 4,000 times or more.

In general, in the ECC processing, error detection exceeding the correction capability is enabled by using more parity data and increasing the amount of information used for error correction. Since an increase in the amount of information (an increase in the number of parity data bits) results in complicated calculation processing, a practical model that has a minimum correction capability is required.

### [0-1-2] Practical Models

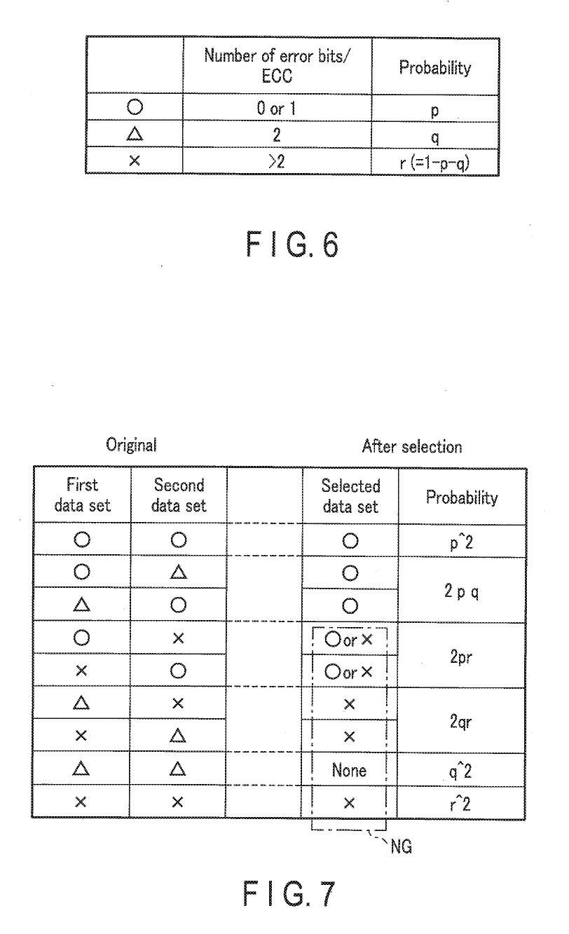

Practical models of the error correction method of the embodiment will be described with reference to FIGS. 6 through 12. The practical models differ from the approximate models described above in that three states which may occur in actual ECC processing are used, as shown in FIG. 6, and in that the majority rule is used.

In FIG. 6, the symbol “∘” represents a normal state where the number of error bits in one-time ECC processing is either 0 or 1 and the probability of occurrence of this state is p. The symbol “∘” represents an error-free state or a state where a detected error is correctable. The symbol “Δ” represents a first error occurrence state where the number of error bits in one-time ECC processing is 2 and the probability of occurrence of this state is q. The symbol “Δ” indicates a state where an error is detected but cannot be corrected. The symbol “x” represents a second error occurrence state where the number of error bits in one-time ECC processing is more than 2 and the probability of occurrence of this state is r (provided that p+q+r=1, and r<q<p). The symbol “x” indicates an error occurrence state where two or more errors cannot be detected and therefore cannot be corrected.

In this practical model, the non-error state “∘” and the second error occurrence state “x” (which contains two or more errors) look like the same, and it is not possible to determine which of the two is the normal state. In other words, in the practical model, the non-error state “∘” and the second error occurrence state “x” (which contains two or more errors) are states which cannot be discriminated from each other.

In contrast, the first error occurrence state “Δ” can be regarded as an error occurrence state with certainty. In addition, the first error occurrence state “Δ” is a state where an error cannot be corrected, as mentioned above, and should be excluded from error correction targets.

Therefore, where a plurality of data sets are used, data sets of the first error occurrence state “Δ” are excluded from the practical model, data sets having a minimum number of error bits are selected from the remaining data sets based on the majority rule. Since the probability of a data set being in the second error occurrence state “x” is low, the probability that a plurality of data sets are identical data in the second error state is negligibly low. That is, data sets in the normal state “∘” can be selected with a high probability from the remaining data sets based on the majority rule.

At the outset, an example of a case where a data set having a minimum number of errors is selected from between two data sets and the probability related to this example will be described with reference to FIG. 7. This example includes a first data set and a second data set, each of which assumes state “∘”, “Δ” or “x”. There are nine combinations between the states of the first and second data sets (9=3̂2). The probabilities of the nine combinations can be represented as {p̂2, pq, pq, pr, pr, qr, qr, q̂2, r̂2}, which are obtained by expanding (p+q+r)̂2.

In each combination, the probability that a data set of the normal state “∘” can be selected based on the majority rule from the data sets from which data sets of the first error occurrence state “Δ” is excluded is p̂2+2pq. The probability that a data set of the normal state “∘” cannot be selected based on the majority rule (NG probability) is 2pr+2qr+q̂2+r̂2. To supplement the explanation, the NG probability corresponds to the following three cases: the first case where it is uncertain which state, the normal state “∘” or the second error occurrence state “x”, is selected; the second state where the second error occurrence state “x” is selected; and the third state where no data state is selected (this state is indicated by “None” in FIG. 7). The NG probability is a small value since the probabilities q and r of the first and second error occurrence states are small.

In other words, where two data sets are used, the read processing fails with a probability of “2pr+2qr+q̂2+r̂2” and succeeds with a probability of “p̂2+2pq”. Therefore, the yield of the read processing that is performed for all data is (the probability of success)̂(number of times ECC processing is performed)=p̂2+2pq)̂(M/n)=(1−(2pr+2qr+q̂2+r̂2))̂(M/n).

Where there is only one data set, the probability of the data set assuming error occurrence state “∘” or “x” is “q+r”. The yield of the read processing for all data is (1−(q+r))̂(M/n).

Therefore, where two data sets are used, the probability of failure of the read processing decreases from “q+r” (which is the probability of the case where one data set is used) to “2pr+2qr+q̂2+r̂2”. In accordance with this, the yield of the read processing of the case where two data sets are used increases from “(1−(q+r))̂(M/n)” to “(1−(2pr+2qr+q̂2+r̂2))̂(M/n)”.

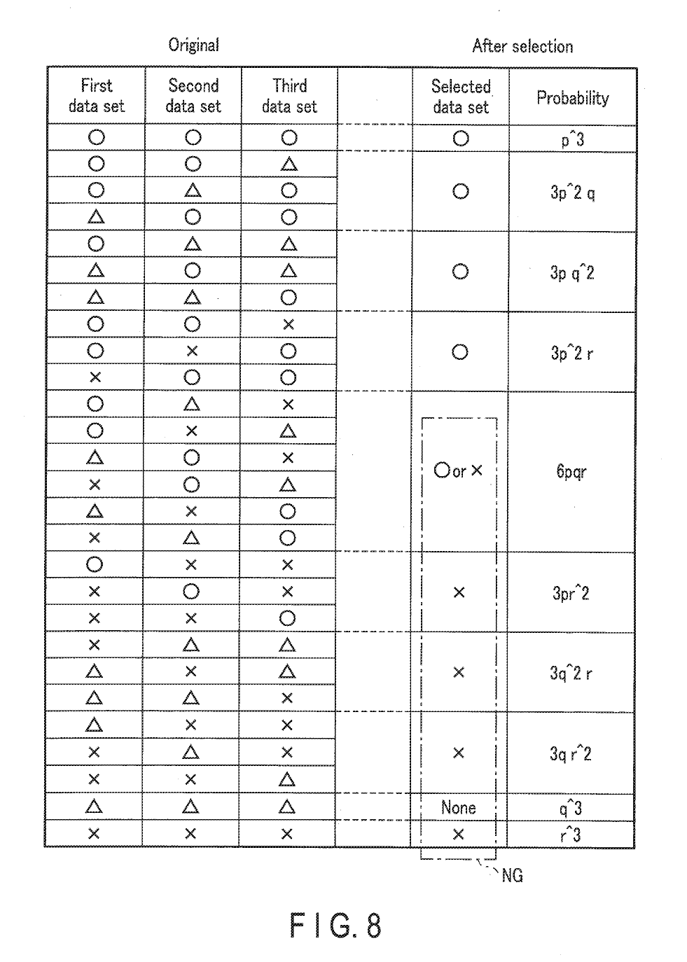

Next, an example of a case where a data set having a minimum number of errors is selected from among three data sets and the probability related to this example will be described with reference to FIG. 8. There are 27 combinations between the states of the first, second and third data sets (27=3̂3). The probabilities of the 27 combinations can be represented as shown in FIG. 8 by expanding (p+q+r)̂3.

In each combination, the probability that a data set of the normal state “∘” can be selected based on the majority rule from the data sets from which data sets of the first error occurrence state “Δ” is excluded is p̂3+3p̂2q+3pq̂2+3p̂2r. The probability that a data set of the normal state “∘” cannot be selected based on the majority rule (NG probability) is 6pqr+3pr̂2+3q̂2r+3pr̂2+q̂3+r̂3.

In other words, where three data sets are used, the read processing fails with a probability of “6pqr+3pr̂2+3q̂2r+3pr̂2+q̂3+r̂3” and succeeds with a probability of “p̂3+3p̂2q+3pq̂2+3p̂2r”. The yield of the read processing for all data is (p̂3+3p̂2q+3pq̂2+3p̂2r)̂(M/n)=(1−(6pqr+3pr̂2+3q̂2r+3pr̂2+q̂3+r̂3))̂(M/n).

Therefore, where three data sets are used, the probability of failure of the read processing decreases from “q+r” (which is the probability of the case where one data set is used) to “6pqr+3pr̂2+3q̂2r+3pr̂2+q̂3+r̂3”. In accordance with this, the yield of the read processing of the case where three data sets are used increases from “(1−(q+r))̂(M/n)” to “(1−(6pqr+3pr̂2+3q̂2r+3pr2+q̂3+r̂3))̂(M/n)”.

Next, an example of a case where a data set having a minimum number of errors is selected from among four data sets and the probability related to this example will be described with reference to FIGS. 9 through 11. There are 81 combinations between the states of the first to fourth data sets (81=3̂4). The probabilities of the 81 combinations can be represented as shown in FIGS. 9 to 11, by expanding (p+q+r)̂4.

In each combination, the probability that a data set of the normal state “∘” can be selected based on a majority rule from the data sets from which data sets of the first error occurrence state “Δ” is excluded is p̂4+4p̂3q+6p̂2q̂2+4pq̂3+4p̂3r+12p̂2qr. The probability that a data set of the normal state “∘” cannot be selected based on a majority rule (NG probability) is 6p̂2r̂2+4pr̂3+12pq̂2r+12pgr̂2+6q̂2r̂2+4q̂3r+4qr̂3+q̂4+r̂4.

In other words, where four data sets are used, the read processing fails with a NG probability and succeeds with a probability of “1−NG probability”. The yield of the read processing for all data is ((1−NG probability)̂(M/n)=(1−(6p̂2r̂2+4pr̂3+12pq̂2r+12pqr̂2+6q̂2r̂2++4q̂3r+4qr̂3+q̂4+r̂4))̂(M/n).

Therefore, where four data sets are used, the probability of failure of the read processing decreases from “q+r” (which is the probability of the case where one data set is used) to “6p̂2r̂2+4pr̂3+12pq̂2r+12pqr̂2+6q̂2r̂2+4q̂3r+4qr̂3+q̂4+r̂4”. In accordance with this, the yield of the read processing of the case where four data sets are used increases from “(1−(q+r))̂(M/n)” to “(1−(6p̂2r̂2+4pr̂3+12pq̂2r+12pqr̂2+6q̂2r̂2+4q̂3r+4qr̂3+q̂4+r̂4))̂(M/n)”.

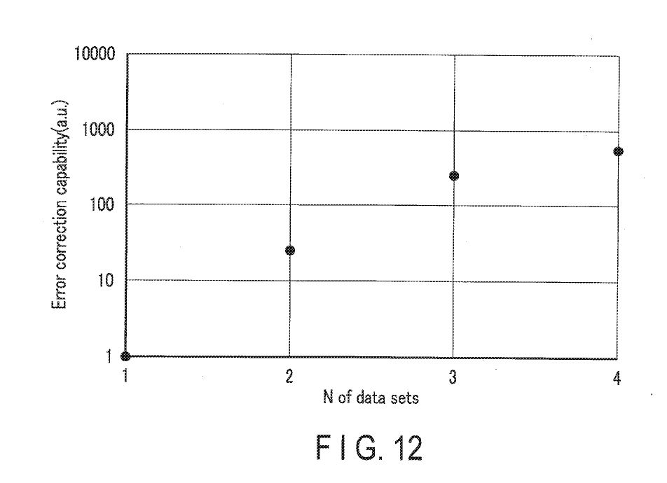

FIG. 12 illustrates how the number of data sets and error correction capability are related. It is assumed here that the ECC processing shown in FIGS. 6 to 11 uses Hamming codes, and that the error correction capability provides a reliability of 1,000 FIT for a memory capacity of 1 Gbit, using 64-bit data and an 8-bit parity. (“FIT” stands for Failure In Time and indicates an error occurrence rate for a time of 10⁹ hours [=10 million hours]). As shown in FIG. 12, the error correction capability increases in accordance with an increase in the number of data sets. Where two data sets are used, the error correction capability increases by 20 times or more (e.g., 25 times). Where three data sets are used, the error correction capability increases by 200 times or more (e.g., 250 times). Where four data sets are used, the error correction capability increases by 500 times or more (e.g., 550 times).

For the sake of simplicity, it is assumed in the model that 1-bit correction is performed using a Hamming code, and that error detection is performed using an additional parity bit, which indicates whether the total number of data bits and parity bits added for error correction is an even number or an odd number (0/1). Not only the Hamming code but also a BCH code (used for correcting two or more error bits) can be used for error correction. Where an ECC capable of correcting N-bit error is used, the numbers of error bits corresponding to “∘”, “Δ” and “x” (FIG. 6) of the model are generalized as follows:

∘: N bits

Δ: N+1 bits

x: N+2 bits

The error bits described in relation to the present model encompasses a defect due to a bit data change caused by reliability degradation or a radiation factor, and an error which may occur with a certain probability when data is read, written or retained.

### First Embodiment

A memory device and a memory system according to the first embodiment will be described.

### <1-1> Configuration

### [1-1-1] Configuration of Memory Device

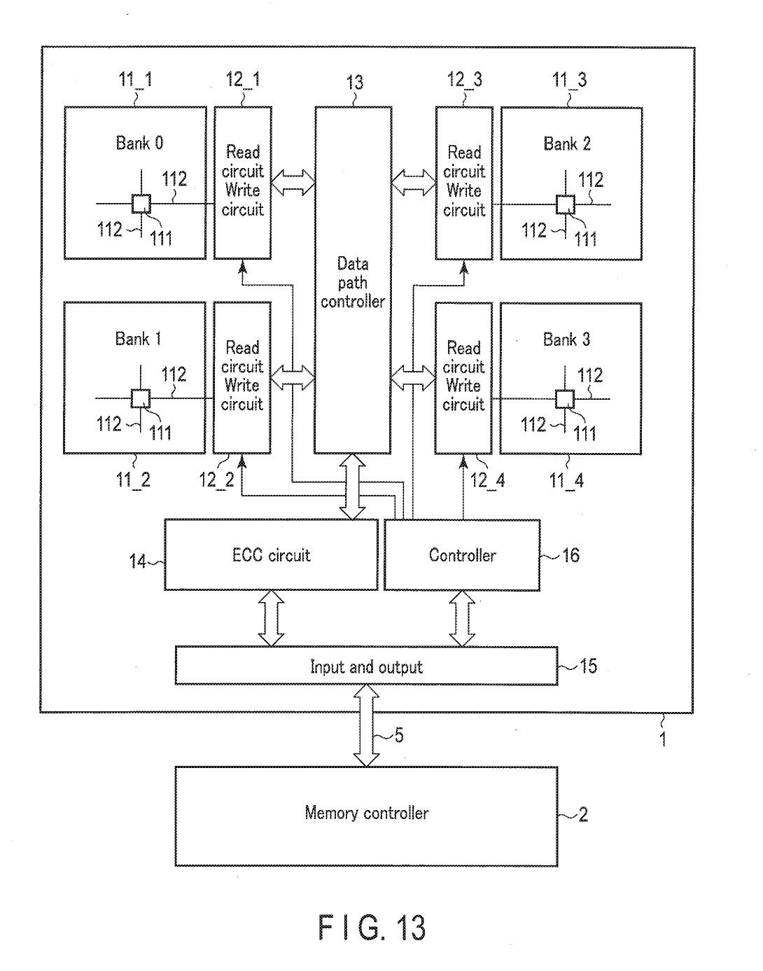

FIG. 13 illustrates function blocks of a memory system according to the first embodiment. This memory system comprises a memory device 1 and a memory controller 2. The memory device 1 is a RAM and is fabricated as one semiconductor chip. The memory device 1 can be implemented as any type of RAM. The memory device 1 is configured to store data in a known method. To be specific, the memory device 1 can be a dynamic RAM (DRAM), a magnetoresistive RAM (MRAM), a resistive RAM (ReRaM) or a phase change RAM (PCRAM). The first embodiment is not limited by the data storage method used by the memory device 1. With respect to the memory device 1, features (including structural elements and connections) known to those skilled in the art differ, depending upon the types of RAMs. For this reason, FIG. 13 shows elements that are generally included in a RAM. Depending upon the type of RAM, the memory device 1 may include function blocks different from those shown in FIG. 13, and the function blocks of the memory device 1 are not limited to those included in the example shown in FIG. 13.

The memory device 1 is connected to the memory controller 2 by connection lines 5 so that the memory device 1 can communicate with the memory controller 2. The connection lines include, for example, a power supply line, a data bus and a command line. The memory controller 2 supplies commands to the memory device 1 and controls the memory device 1 by the commands. To be more specific, the memory controller 2 instructs the memory device 1 to write data therein, or instructs the memory device 1 to read specific data therefrom.

As shown in FIG. 13, the memory device 1 includes a plurality of banks 11. In FIG. 13, four banks 11_1 to 11_4 are shown by way of example. Where elements indicated by reference symbols that have an under bar and a subsequent symbol or number at the end need not be discriminated from each other, the under bar and subsequent symbol or number will be omitted from the reference symbols. Descriptions using such reference symbols are applicable to all elements indicated by reference symbols including the under bar and the subsequent letter or symbol. Each bank 11 is configured to store data and is provided with elements including, at least, a plurality of memory cells 111 and various signal lines 112. In the present embodiment, the banks 11 constitute memory circuits that store the same data and a parity corresponding to the data. Four banks 11_1 to 11_4 correspond to the example shown in FIGS. 9 to 11, wherein four data sets are stored.

Four banks 11_1 to 11_4 may be modified as two banks 11_1 and 11_2 in such a manner that the modified two banks correspond to the example shown in FIG. 7, wherein two data sets are stored. In accordance with this modification, attendant circuits 12_1 to 12_4 (mentioned below) are modified as circuits 12_1 and 12_2, and ECC decoders 142_1 to 142_4 are modified as ECC decoders 142_1 and 142_2. Four banks 11_1 to 11_4 may be modified as three banks 11_1 to 11_3 in such a manner that the modified three banks correspond to the example shown in FIG. 8, wherein three data sets are stored. In accordance with this modification, attendant circuits 12_1 to 12_4 are modified as circuits 12_1 to 12_3, and ECC decoders 142_1 to 142_4 are modified as ECC decoders 142_1 and 142_3.

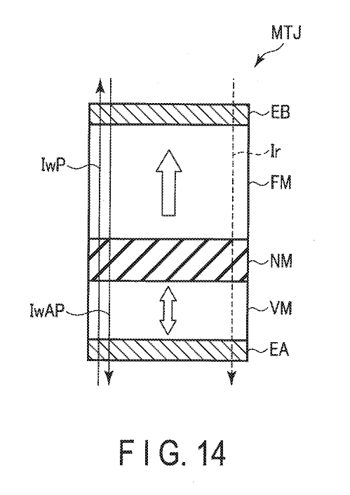

The detailed structure of banks 11 differs, depending upon the type of RAM (i.e., memory device 1). For example, if the memory device 1 is an MRAM, bank 11 is configured to retain data in the memory cell 111 by utilization of the magnetoresistive effect. The memory cell of the MRAM includes a magnetic tunnel junction (MTJ) element and retains data in the nonvolatile manner in accordance with the state of magnetization. The MTJ element includes an MTJ. As shown in FIG. 14, the MTJ includes two magnetic layers FM and VM and a nonmagnetic layer NM located between the two magnetic layers FM and VM. Magnetic layer FM has a fixed direction of magnetization, and magnetic layer VM has a variable direction of magnetization. Magnetic layers FM and VM have axes of easy magnetization that are perpendicular to the interfaces of layers FM, NM and VM (the axes of easy magnetization are indicated by arrows). Magnetic layers FM and VM may have axes of easy magnetization that are parallel to the interfaces of layers FM, NM and VM. Layers FM, NM and VM are located between electrodes EA and EB.

The MTJ element has a minimal resistance when the axes of easy magnetization of magnetic layers FM and VM are parallel to each other, and has a maximal resistance when the axes of easy magnetization are antiparallel to each other. Two transition states showing different resistances are assigned to binary data. For example, the parallel axes of magnetization of magnetic layers FM and VM are correlated with the state where “0” bit is retained, and the antiparallel axes of magnetization of magnetic layers FM and VM are correlated with the state where “1” bit is retained When write current IwP flows from magnetic layer VM to magnetic layer FM, the magnetization directions of magnetic layers FM and VM become parallel (“0” data is written in the MTJ element). On the other hand, when write current IwAP flows from magnetic layer FM to magnetic layer VM, the magnetization directions of magnetic layers FM and VM become antiparallel (“1” data is written in the MTJ element). Currents IwP and IwAP are larger than threshold Ic at which the MTJ element inverts in state. Read current Ir is made to flow through the MTJ element, for the detection of the resistance of the MTJ element. For example, current Ir flows in the same direction as the current for writing “1” data, but has a smaller value than that of the current for writing “1” data.

If the memory device 1 is a DRAM, the bank 11 is configured to retain data in the memory cell 111 by utilization of the charge accumulation. The memory cell of the DRAM includes a capacitor and retains data in the nonvolatile manner in accordance with the charge of the capacitor.

If the memory device 1 is a ReRAM or PCRAM, the bank 11 is configured to retain data in the memory cell 111 by utilization of a resistance change. The memory cell of the ReRAM includes a resistance change element made of a metallic oxide or a perovskite oxide. The state of resistance is changed by varying the pulse width (pulse application period), the amplitude (current value/voltage value) and the polarity (application direction) of a write pulse. The memory cell of the PCRAM includes a phase change element (resistance change element) made of chalcogenide or the like. The state of resistance is changed when the film in the phase change element is changed into a crystalline state or an amorphous state due to the heat caused by the write current.

The signal lines 112 include bit lines, word lines, etc. The banks BA include a control circuit (not shown) for the respective banks.

The memory device 1 comprises attendant circuits 12_1 to 12_4. The attendant circuits 12_1 to 12_4 are provided for the banks 11_1 to 11_4, respectively. Each of the attendant circuits 12 controls the corresponding bank 11 and includes, for example, a read circuit and a write circuit. Each of the read and write circuits includes a driver, a decoder, a page buffer, a sense amplifier, etc. The decoder selects a memory cell 111 specified by an address signal supplied from the memory controller 2. The page buffer temporarily stores data to be supplied to the corresponding bank 11 or data supplied from that bank 11. The read circuit identifies data supplied from the selected memory cell 111. The write circuit writes designated data in the selected memory cell 111.

The memory device 1 further comprises a data path controller 13, an error correction code (ECC) circuit 14, an input/output circuit 15 and a controller 16. The data path controller 13 is connected between the attendant circuits 12 and the ECC circuit 14. The data path controller 13 is connected to all attendant circuits 12 and includes a plurality of signal lines (a bus). The data path controller 13 serves to connect one or more attendant circuits 12 to the ECC circuit 14. The input/output circuit 15 controls the signal transmission between the memory device 1 and the memory controller 2. The input/output circuit 15 receives write data from the memory controller 2 and supplies it to the ECC circuit 14. Likewise, the input/output circuit 15 receives write data from the ECC circuit 14 and supplies it to the memory controller 2. In addition, the input/output circuit 15 receives a command and an address signal from the memory controller 2 and supplies them to the controller 16. The controller 16 includes elements, such as a command decoder, a latch, a buffer and a voltage generator, and controls the structural elements of the memory device 1 based on the received command and address signal.

### [1-1-2] Configuration of ECC Circuit

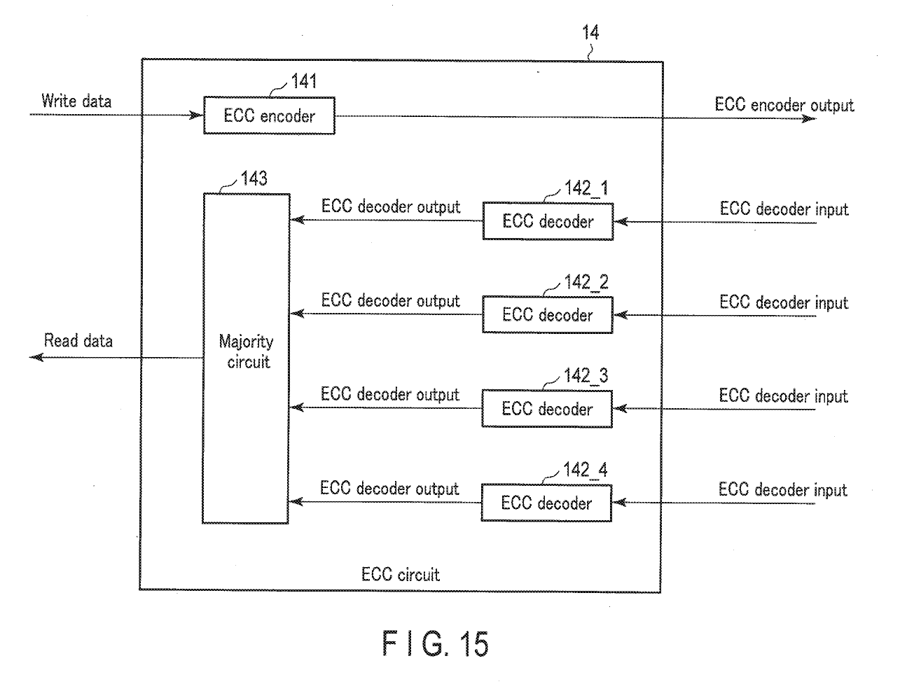

As shown in FIG. 15, the ECC circuit 14 includes an ECC encoder 141, a plurality of ECC decoders 142_1 to 142_4, and a majority circuit 143.

The ECC encoder 141 receives write data (i.e., a bit sequence of “1” or “0”), generates an error correction code (parity bit) for each division unit (ECC word) of the write data in accordance with a principle described later and a predetermined error correction code generating rule, and outputs a pair of write data and parity bit (an ECC encoder output). To be more specific, the ECC encoder 141 generates a parity bit from the received write data according to the predetermined error correction code generating rule, couples the generated parity bit with the write data, and outputs the resultant data as an ECC encoder output.

At the time of reading, ECC decoders 142_1 to 142_4 receive data from banks 11_1 to 11_4, respectively. Since the data from the banks is received by the ECC decoders 142, the data will be referred to as “ECC decoder input” as well in the description below. Like the ECC encoder output, the ECC decoder input includes a pair of (i) data to be read (namely, read data) and (ii) a parity bit. The ECC decoder input includes an ECC encoder output and may further include an error.

Where the data read from the banks 11 includes one error, the ECC decoders 142 correct the error, using a parity, and generate a first result including the corrected read data. Where the read data includes one error, the ECC decoders 142 may correct the error, using a parity and a check matrix. Where the read data includes one error, the ECC decoders 142 may correct the error, using a parity and the Hamming method. Where the read data includes two errors, the ECC decoders 142 generate a second result indicating the errors. Where the read data includes no error, the ECC decoders generate a third result including the read data. The read data included in the third result may be data including no error or data including more than two errors.

To be specific, the ECC decoders 142 calculate, for each ECC word unit, a syndrome from an ECC decoder input and a check matrix defined according to a rule mentioned below, correct the errors in the read data of the ECC decoder input, using the syndrome, and supply an ECC decoder output to the majority circuit 143. The error correction capability of the ECC decoders 142 is determined based on the error correction code and is 1 bit, for example.

The majority circuit 143 excludes the second result from the results generated by the ECC decoders 142, selects one of the remaining results based on the majority rule, and outputs read data included in the selected result. For example, the majority circuit 143 receives the ECC decoder outputs, selects one of them according to the majority rule, and outputs the selected ECC decoder output as read data.

Where the first results and third results included in the remaining results are equal in number, the majority circuit 143 may select either the first results or the third results based on a predetermined condition. Where the first results and third results included in the remaining results are equal in number, the majority circuit 143 may randomly select results from the remaining results.

If there is no remaining result, the majority circuit 143 may output a read error.

The ECC circuit 14 will be described in detail.

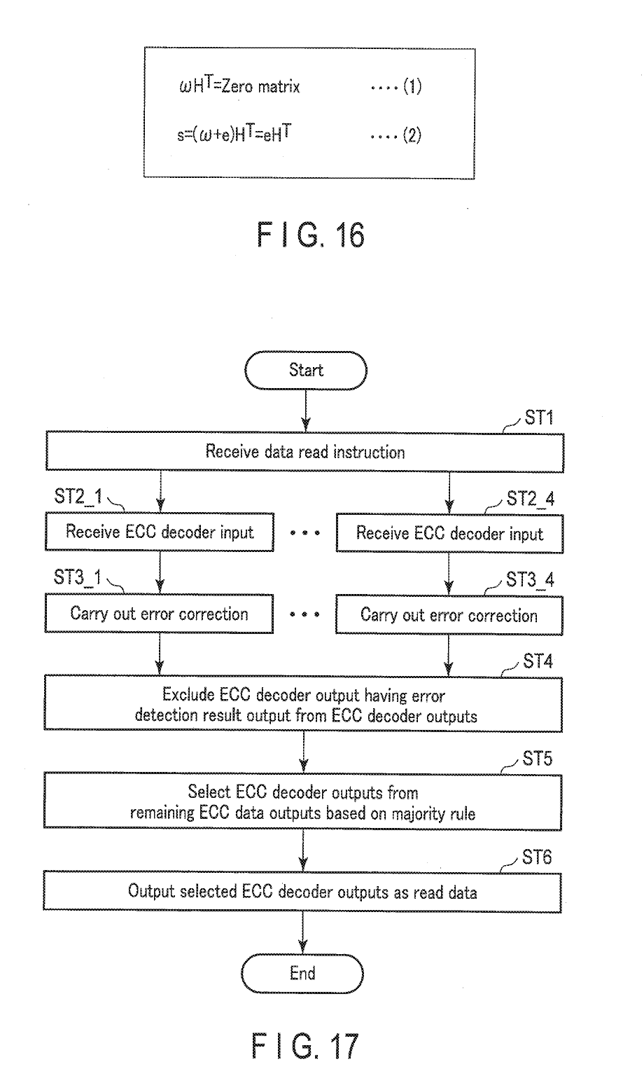

FIG. 16 illustrates a parity bit and check matrix principle, which are used in the ECC circuit 14 of the first embodiment, especially in the ECC encoder 141 and ECC decoders 142. In FIG. 16, the symbol “w” is a code word and corresponds to an ECC encoder output that is written in the banks 11 and thereafter read from the banks 11. The symbol “H” is a check matrix and is used by the ECC decoders 142, for error correction. The symbol “s” is a syndrome, and the symbol “e” is an error in an ECC encoder output. The parity bit and check matrix used by the ECC encoder 141 and the ECC decoders 142 are determined in such a manner as to satisfy formulas (1) and (2) in FIG. 16. Any kind of code can be used as a parity bit as long as it satisfies formulas (1) and (2) in conjunction with the check matrix. For example, a Hamming code, a BCH code, a Reed-Solomon code or the like can be used as a parity bit. To prevent the calculation related to error correction from becoming complex, the present embodiment uses a Hamming code capable of correcting a 1-bit error.

Formula (1) shows a general principle for error correction. That is, check matrix H^{T} is defined such that the product between the check matrix H^{T} and the code word ω containing no error generates a zero matrix. If error e is contained in the code word w, as indicated by formula (2), the syndrome s obtained by multiplying the error-containing code word (ω+e) by the check matrix H^{T} is matrix eH^{T}.

By defining the parity bit and the check matrix H^{T} satisfying formulas (1) and (2), an error in an ECC decoder input can be corrected using a parity bit.

### [1-2] Operation

A description will be given as to how the ECC circuit operates in the semiconductor device and memory system of the embodiment.

### [1-2-1] Write Operation

When write data supplied from the memory controller 2 is received from the input/output circuit 15, the ECC circuit 14 operates as follows. The write data is received by the ECC encoder 141. The ECC encoder 141 calculates a parity bit from the write data according to the rule made with reference to FIG. 16. The ECC encoder 141 couples the parity bit with the write data and outputs the resultant data as an ECC encoder output.

The ECC encoder output is supplied via the data path controller 13 to a bank 11 to which it is to be written. The bank 11 writes the ECC encoder output in its memory cell 111.

### [1-2-2] Read Operation

As shown in FIG. 17, the memory device 1 receives a specific data read instruction from the memory controller 2 (ST1). Upon receipt of the specific data read instruction, the memory device 1 reads data sets (in which data (read data) and a parity bit are coupled) from banks 11_1 to 11_4. The four data sets are supplied to the ECC circuit 14 as four ECC decoder inputs. The ECC decoder inputs are received by ECC decoders 142_1 to 142_4 (ST2_1 to ST2_4). As described above, each of the ECC decoder inputs includes an ECC encoder output and may further include an error.

ECC decoders 142_1 to 142_4 carry out error correction processing for the received ECC decoder inputs (ST3_1 to ST3_4).

To be specific, ECC decoders 142_1 to 142_4 calculate syndromes by multiplying the received ECC decoder inputs by the check matrix H^{T}. The ECC decoders 142 determine the types of syndromes as calculation results.

If the syndrome is a zero matrix (i.e., the case indicated by formula (1) in FIG. 16), the read data included in the ECC decoder input contains no error. Accordingly, the corresponding ECC decoder 142 does not perform error correction for the read data included in the ECC decoder input, and supplies an ECC decoder output including the read data to the majority circuit 143.

If the syndrome is a matrix eH^{T} (i.e., the case indicated by formula (2)), the read data included in the ECC decoder input contains an error. Accordingly, the corresponding ECC decoder 142 corrects the error in the read data, using a parity bit, and supplies read data in which the error is corrected (namely, error-corrected read data) to the majority circuit 143 as an ECC decoder output.

If the syndrome is neither the zero matrix nor matrix eH^{T}, it is determined that the error in the ECC decoder input exceeds the error correction capability of the ECC decoder 142. For example, if the error correction capability of the ECC decoder 142 is “1 bit”, the syndrome is neither the zero matrix nor matrix eH^{T}. In this case, it is determined that the read data includes a 2-bit error. Although the ECC decoder 142 cannot correct an error exceeding its correction capability, it can detect an error of (correction capability+1 bit). The ECC decoder 142 outputs a message to the effect that the read data include an error that cannot be corrected (i.e., an error of (correction capability+1 bit)), and supplies this message to a device external to the memory device 1.

The majority circuit 143 excludes an error-detected ECC decoder output from the ECC decoder outputs received from the ECC decoders 142 (ST4), and selects a largest number (majority) of ECC decoder outputs from the remaining ECC data outputs (ST5).

With respect to steps ST4 to ST5, there are 81 states, as shown in FIGS. 9 to 11. The 81 states are classified as four cases (a) to (d), and the “data set” in FIGS. 9-11 will be mentioned as “ECC decoder outputs” in the description below. The four cases described below are: (a) the case where an ECC decoder output in the normal state “∘” is selected; (b) the case where an ECC decoder output in the second error occurrence state “x” is selected; (c) the case where an ECC decoder output in the normal state “∘” or in the second error occurrence state “x” is selected; and (d) no ECC decoder output is selected. Case (a) corresponds to selected data set “∘” in FIGS. 9 to 11, and case (b) corresponds to selected data set “x” in FIGS. 9 to 11. Case (c) corresponds to selected data set “∘ or x” in FIGS. 9 to 11, and case (d) corresponds to selected data set “None” in FIGS. 9 to 11.

An ECC decoder output excluded in step ST4 is an ECC decoder output in the first error occurrence state “A”. It should be noted that none of the ECC decoder outputs received from ECC decoders 142_1 to 142_4 are in the first error occurrence state “Δ”, no ECC decoder output is excluded in step ST4. At any rate, after step ST4, there are the following two cases: the case where the ECC data outputs include at least one of an ECC decoder output in the normal state “∘” and an ECC decoder output in the second error occurrence state “x”, and the case where no ECC data output remains. In the former case, the ECC decoder outputs selected in step ST5 correspond to the largest number of ECC decoder outputs, which are included in the combinations of the ECC decoder outputs in the normal state “∘” and the ECC decoder outputs in the second error occurrence state “x”. In the latter case, none is selected in step ST5 since there is no remaining ECC decoder output.

(a) Case where ECC Decoder Output in the Normal State “∘” is Selected

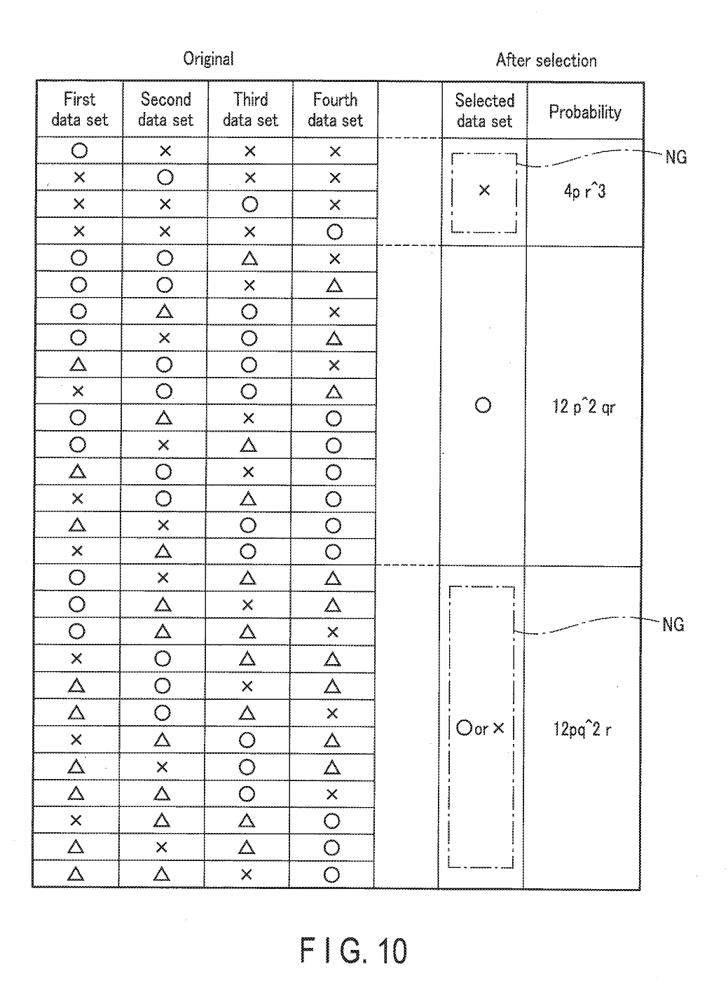

Let us consider the case shown in the fifth row in FIG. 10, i.e., the case where there are two ECC decoder outputs in the normal state “∘”, one ECC decoder output in the first error occurrence state “∘”, and one ECC decoder output in the second error occurrence state “x”. In this case, the ECC decoder output in the first error occurrence state “Δ” is excluded in step ST4, and two ECC decoder outputs in the normal state “∘” and one ECC decoder output in the second error occurrence state “x” remain. In step ST5, ECC decoder outputs in the normal state “∘” are selected from the remaining ECC decoder outputs as the largest number of ECC decoder outputs.

(b) Case where ECC Decoder Output in the Second Error Occurrence State “x” is Selected

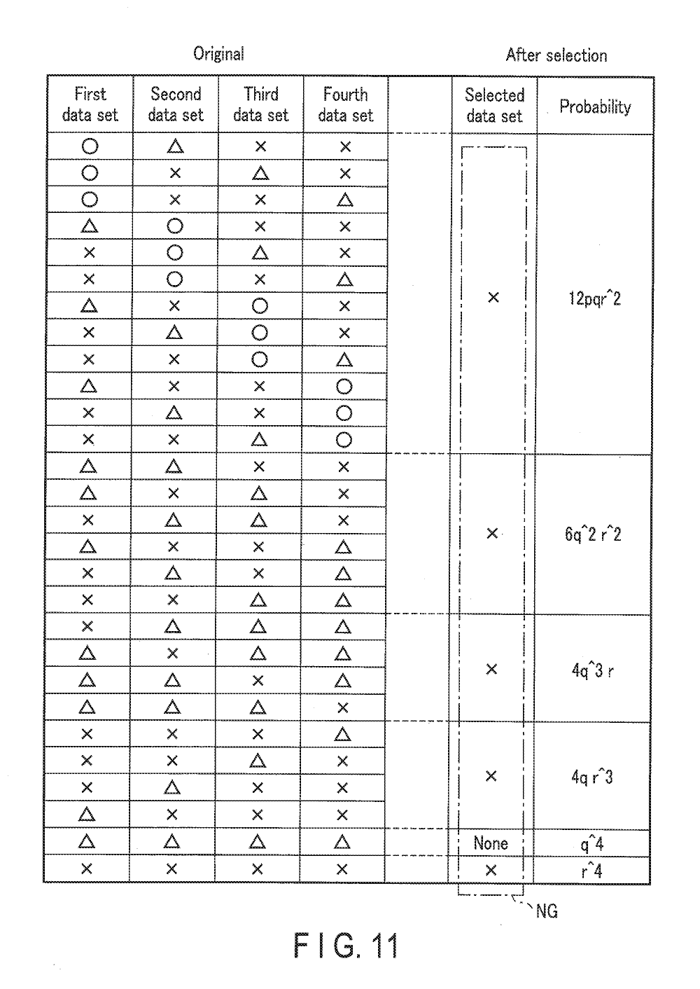

Let us consider the case shown in the first row in FIG. 11, i.e., the case where there are one ECC decoder output in the normal state “∘”, one ECC decoder output in the first error occurrence state “Δ”, and two ECC decoder outputs in the second error occurrence state “x”. In this case, the ECC decoder output in the first error occurrence state “Δ” is excluded in step ST4, and one ECC decoder output in the normal state “∘” and two ECC decoder outputs in the second error occurrence state “x” remain. In step ST5, the ECC decoder outputs in the second error occurrence state “x” are selected from the remaining ECC decoder outputs as the largest number of ECC decoder outputs.

The probability that the ECC decoder outputs in the second error occurrence state “x” are selected is negligibly low, since this corresponds to a state where the same number of errors occur in both the ECC decoder outputs. To supplement the explanation, the three probabilities p, q and r shown in FIG. 6 satisfy the relation r<q<p. Therefore, the probability r of occurrence of the second error state “x” is low, and the probability r̂2 of occurrence of two second error states is still lower. In addition, the probability that two second error occurrence states have identical patterns is lower than probability r̂2. That is, the probability that the ECC decoder outputs in the second error occurrence state “x” are selected is negligibly low.

(c) Case where ECC Decoder Output in the Normal State “∘” or in the Second Error Occurrence State “x” is Selected

Let us consider the case shown in the last row in FIG. 10, i.e., the case where there are one ECC decoder output in the normal state “∘”, two ECC decoder outputs in the first error occurrence state “Δ”, and one ECC decoder output in the second error occurrence state “x”. In this case, the two ECC decoder outputs in the first error occurrence state “Δ” are excluded in step ST4, and one ECC decoder output in the normal state “∘” and one ECC decoder output in the second error occurrence state “x” remain. In step ST5, the ECC decoder output in the second error occurrence state “x” should be selected from the remaining ECC decoder outputs as the largest number of ECC decoder outputs.

In this case, however, the ECC decoder output in the normal state “∘” and the ECC decoder output in the “x” state are equal in number, the largest number of ECC decoder outputs cannot be selected based on the majority rule.

For this reason, where the ECC decoder output in the normal state “∘” and the ECC decoder output in the “x” state are equal in number, the majority circuit 143 selects either of the remaining ECC decoder outputs in the following method: For example, where the ECC decoder output in the normal state “∘” and the ECC decoder output in the “x” state are equal in number, the majority circuit 143 may select either of the remaining ECC decoder outputs based on a predetermined condition. The condition is, for example, determining priorities of the respective four decoders 142_1 to 142_4 or the respective banks 11_1 to 11_4. The condition is not limited to this, and the selection may be made based on the values of read data, e.g., the descending (or ascending) order of the values of the bit columns of read data. The majority circuit 143 may perform selection without using any condition. For example, where the ECC decoder output in the normal state “∘” and the ECC decoder output in the “x” state are equal in number, the majority circuit 143 may randomly select either of the remaining ECC decoder outputs. The method for random selection may use a random number generated based on a random number table or by a random number generator.

(d) Case where No ECC Decoder Output is Selected

Let us consider the case shown in the penultimate row in FIG. 11, i.e., the case where there are four ECC decoder outputs in the first error occurrence state “Δ”. In this case, all ECC decoder outputs in the first error occurrence state “Δ” are excluded in step ST4, and no ECC decoder output remains. None is selected in step ST5 since there is no remaining ECC decoder output.

It should be noted that probability q̂4 that none is selected is negligibly low. To supplement the explanation, the probability q̂4 that four ECC decoder outputs in the first error occurrence state “Δ” is (1/3)̂4=1/81, provided that q=p=r=1/3. In practice, the probability q̂4 is negligibly low because of the relations r<q<1/3<p.

In case (a), (b) or (c), after step ST5, the majority circuit 143 outputs the selected ECC decoder outputs as read data (ST6). In case (d), after step ST5, the majority circuit 143 outputs an error message (a read error) as read data.

The read data output from the majority circuit 143 is supplied to a device external to the memory device 1 by way of the input/output circuit 15.

### [1-3] Advantages of First Embodiment

According to the present embodiment, an ECC decoder output having a smallest number of errors is selected from a plurality of banks 11_1 to 11_4, in which the same data is stored. Therefore, the error correction capability is enhanced and the calculation required for error correction is reduced. Accordingly, fast data access is enabled by the memory device and memory system.

Advantages of the present embodiment will be described, referring to error correction methods (i) and (ii) in which error data in a memory is corrected. Method (ii) will be referred to as a comparative example. In general, an Error Correction Code (ECC) method, such as the Hamming method, is used as an error correction method.

In method (i), redundant spare data is stored in a memory, and if a defective memory portion is detected, the data in the defective memory portion is replaced with the spare bits. Method (i) is mainly used for remedying a defect caused at the time of manufacturing a memory.

In method (ii) of comparative example, a parity bit of a predetermined length used for error correction is added to data of a certain length. When data is written, restoration data is written in the parity bit and is used if an error occurs. When a memory or a memory system is used, the method (ii) of comparative example is used for correcting errors in data for restoration, which are caused by electric stress during use, external stress such as cosmic rays, and accidental data inversion of a memory element

Where 2-bit or 3-bit correction capability is used in place of 1-bit correction capability, the method (ii) of the comparative example has problems in that the calculation for error correction becomes complex and the calculation time is lengthened, in accordance with an increase in the error correction capability. As a result, data access performance of the memory is degraded.

According to the first embodiment, a data set having a smallest number of errors is selected from a plurality of ECC data of the same data. Therefore, the error correction capability is enhanced and the calculation required for error correction is reduced. Accordingly, fast data access is enabled by the memory device and memory system.

Although the available memory capacity may be reduced, the present embodiment realizes a highly-reliable memory device and memory system which have both a low level of defectiveness and a high-speed performance. According to the present embodiment, the same data is stored in banks 11_1 to 11_4. Although the memory capacity available is reduced thereby, the low level of defectiveness is attained by executing ECC processing of low error correction capability in parallel and selecting data based on the majority rule. In addition, by using the ECC (which is low in error correction capability), the present embodiment ensures effective error correction, and high-speed data access is enabled thereby. Although the available memory capacity is reduced, the present embodiment realizes both a low level of defectiveness and a high-speed performance.

In the present embodiment, the read data included in the third result obtained where no error is detected is data including no error or data including more than two errors. By applying the majority rule to such read data, read data in the second occurrence state, which appears similar to read data in the normal state, can be excluded with a high probability.

Where the first results and third results included in the remaining results are equal in number, the present embodiment may select either the first results or the third results based on a predetermined condition. Even if the majority rule is not applicable, read data can be selected quickly.

Where the first results and third results included in the remaining results are equal in number, the present embodiment may randomly select any one of the first or third results. Even if the majority rule is not applicable, read data can be selected quickly and fairly.

If there is no remaining result, the majority circuit 143 of the present embodiment can output a read error. Even if the majority rule is not applicable, the read error can be output quickly.

According to the present embodiment, where the read data includes one error, the ECC decoders 142 can correct the error, using a parity and a check matrix. Accordingly, efficient error correction is enabled.

According to the present embodiment, where the read data includes one error, the ECC decoders 142 can correct the error, using a parity and a Hamming method. Accordingly, efficient error correction is enabled.

### [1-4] Modifications of First Embodiment

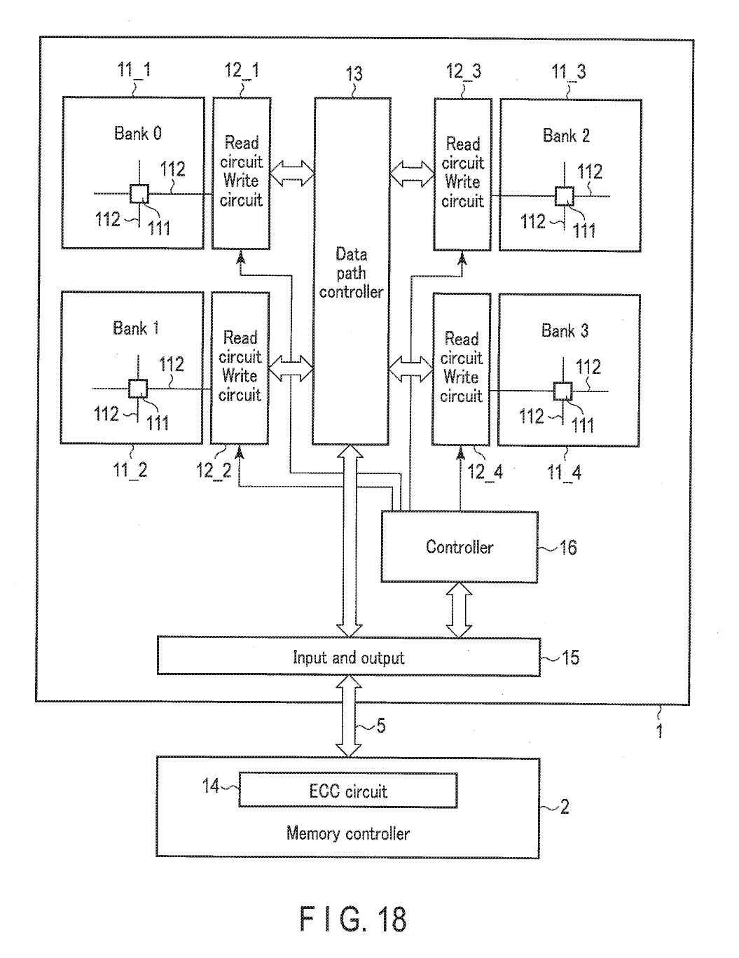

A modification of the memory device and memory system of the first embodiment will be described with reference to FIG. 18. The modification differs from the first embodiment described above in that the ECC circuit 14 is external to the memory device 1. That is, the ECC circuit 14 is provided in the memory controller 2, not in the memory device 1. The memory device 1 and the memory controller 2 are fabricated as different semiconductor chips. The memory controller 2 controls the write operation of the memory device 1, based on signals supplied from an external device (e.g., a host device). The ECC circuit 14, which operates as above, instructs the memory device 1 to write an ECC encoder output in a specific area of a specific bank 11 as write data. The write data is supplied through a connection line 5 and received by the input/output circuit 15 of the memory device 1. Under the control of the controller 16, the input/output circuit 15 supplies the write data to the data path controller 13 as it is. The controller 16 writes the write data supplied to the data path controller 13 in target memory cells 111.

In addition, the memory controller 2 controls the read operation of the memory device 1, based on signals supplied from an external device (e.g., a host device). The memory device 1 receives a specific data read instruction from the memory controller 2. Upon receipt of the specific data read instruction, the memory device 1 reads data sets (in which data (read data) and a parity bit are coupled) from banks 11_1 to 11_4. The four data sets are supplied to the memory controller 2 as four ECC decoder inputs.

The ECC circuit 14, which operates as above, excludes ECC decoder outputs containing an uncorrectable error, from the ECC decoder outputs obtained from four ECC decoder inputs, and selects a largest number of ECC decoder outputs from the remaining ECC decoder outputs. Subsequently, the ECC circuit 14 outputs the selected ECC decoder outputs as read data. If the ECC circuit 14 cannot select any data, the ECC circuit 14 outputs an error message (a read error) as read data. This modification is applicable also to the second embodiment described below.

### Second Embodiment

A memory device and a memory system according to the second embodiment will be described. The present embodiment is a modification of the first embodiment wherein the error correction and the selection based on the majority rule are performed in series. According to the second modification, the ECC circuit 14 performs error detection, selection based on the majority rule and error correction in series. In the following, a description will be given only of the features differentiating the second embodiment from the first embodiment.

### [2-1] Configuration of ECC Circuit

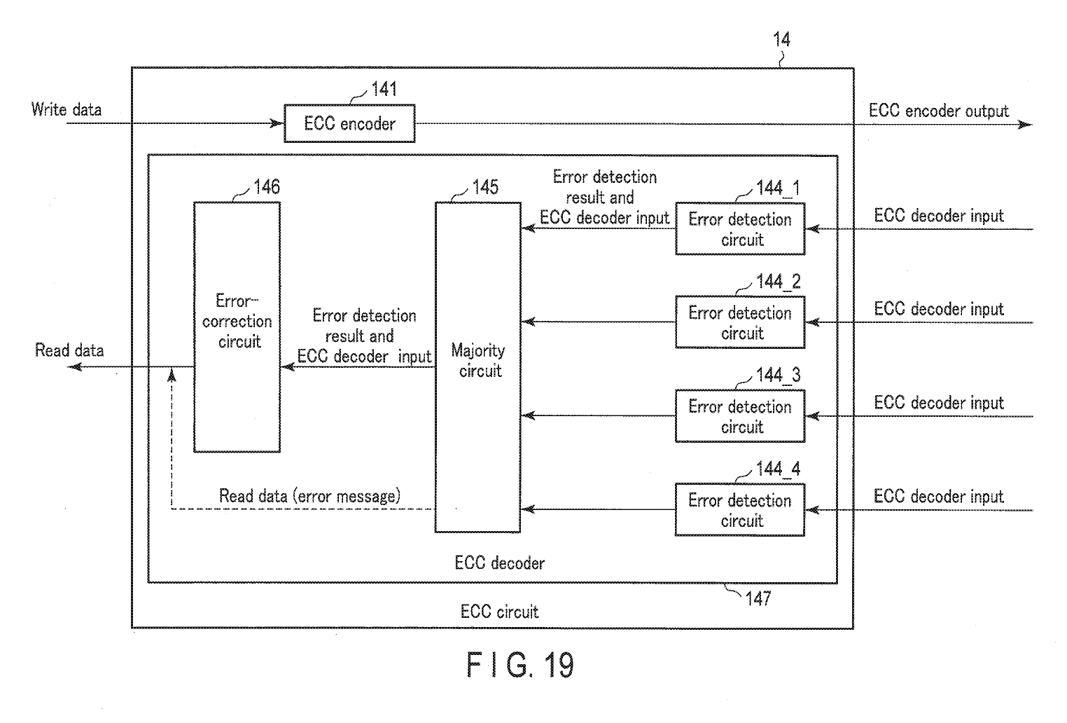

As shown in FIG. 19, the ECC circuit 14 includes an ECC encoder 141, a plurality of error detection circuits 144_1 to 144_4, a majority circuit 145 and an error correction circuit 146. The error detection circuits 144_1 to 144_4, majority circuit 145 and error correction circuit 146 jointly constitute an ECC decoder 147.

The ECC encoder 141 is similar to the ECC encoder described in connection with the first embodiment.

The error detection circuits 144_1 to 144_4 receive ECC decoder inputs from banks 11_1 to 11_4, respectively. As described above, each ECC decoder input includes a pair of read data and a parity bit, and may further include an error.

The error detection circuits 144_1 to 144_4 perform error detection for the read data of the banks 11_1 to 11_4, and generate detection results representing whether or not the read data includes an uncorrectable error. To be specific, the error detection circuits 144_1 to 144_4 calculate, for each ECC word unit, a syndrome from an ECC decoder input and a check matrix defined according to the rule mentioned above, and detect the error in the read data of the ECC decoder input, using the syndrome. The error detection circuits 144_1 to 144_4 supply detection results and the ECC decoder inputs to the majority circuit 145. The detection results include, for example, information representing whether or not an uncorrectable error is included, and may further include a syndrome.

The majority circuit 145 excludes read data including uncorrectable errors, based on the detection results generated by the error detection circuits 144_1 to 144_4, and selects one of the remaining read data based on the majority rule. Where the ECC decoder data in one state and the ECC decoder data in another state are equal in number, the majority circuit 145 may select either of the data based on a predetermined condition. Where the ECC decoder data in one state and the ECC decoder data in another state are equal in number, the majority circuit 145 may randomly select either of the data. If there is no remaining result, the majority circuit 143 may output a read error.

To be specific, the majority circuit 145 receives detection results and ECC decoder inputs, selects a detection result and an ECC data input based on the majority rule from the detection results representing that an uncorrectable error is not included and ECC decoder inputs, and supplies the detection result and ECC data input selected based on the majority rule to the error correction circuit 146.

Where the read data selected by the majority circuit 145 includes one error, the error correction circuit 146 corrects the error, using a parity, and outputs the corrected read data. Where the read data selected by the majority circuit 145 includes no error, the error correction circuit 146 outputs the read data.

To be specific, the error correction circuit 146 receives the selected detection result and ECC decoder input, and corrects the error included in the ECC decoder input, using the syndrome included in the detection result.

### [2-2] Operation

A description will be given as to how the ECC circuit operates in the semiconductor device and memory system of the embodiment.

### [2-2-1] Write Operation

The write operation is performed in the same way as in the first embodiment.

### [2-2-2] Read Operation

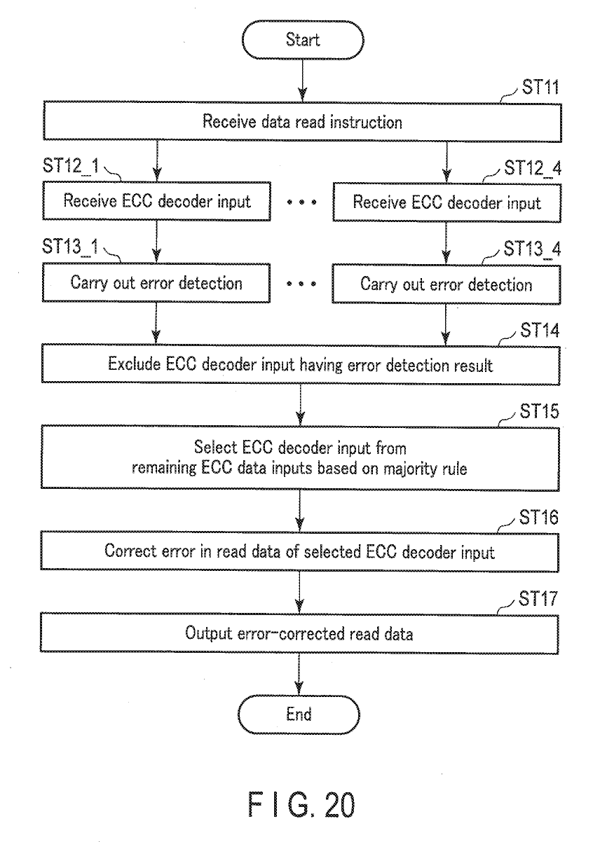

As shown in FIG. 20, the memory device 1 receives a specific data read instruction from the memory controller 2 (ST11). Upon receipt of the specific data read instruction, the memory device 11 reads data sets (in which data (read data) and a parity bit are coupled) from banks 11_1 to 11_4. The four data sets are supplied to the ECC circuit 14 as four ECC decoder inputs. The ECC decoder inputs are received by the error detection circuits 144_1 to 144_4 of the ECC decoder 147 (ST12_1 to ST12_4). As described above, each of the ECC decoder inputs includes an ECC encoder output and may further include an error.

Error detection circuits 144_1 to 144_4 carry out error detection processing for the received ECC decoder inputs (ST13_1 to ST13_4).

To be specific, error detection circuits 144_1 to 144_4 calculate syndromes by multiplying the received ECC decoder inputs by the check matrix H^{T}. The error detection circuits 144_1 to 144_4 determine the types of syndromes as calculation results.

If the syndrome is a zero matrix or a matrix eH^{T}, the read data included in the ECC decoder input does not contain an uncorrectable error. If the syndrome is a zero matrix, the read data included in the ECC decoder input contains no error. If the syndrome is a matrix eH^{T}, the read data included in the ECC decoder input contains a correctable error.

If the syndrome is neither a zero matrix nor a matrix eH^{T}, the read data included in the ECC decoder input contains an uncorrectable error.

Thereafter, the error detection circuits 144_1 to 144_4 supply detection results (which include syndromes and information representing whether or not an uncorrectable error is included) and the ECC decoder inputs to the majority circuit 145. The detection results do not have to include the syndromes, but the inclusion of the syndromes is preferable because the error correction circuit 146 can omit the calculation of the syndromes. If the detection results contain a correctable error, error detection circuits 144_1 to 144_4 may output only detection results; they do not have to output the ECC decoder inputs.

The majority circuit 145 excludes an ECC decoder input including a detection result representing the inclusion of uncorrectable error, from the detection results and ECC decoder outputs inputs (ST14), and selects a largest number (majority) of ECC decoder inputs from the remaining ECC data inputs (ST15). The processing in step ST14 and ST15 is performed in the same way as the above-mentioned processing in step ST4 and ST5 and the processing performed for four cases (a) to (d). In the description below, “step ST4”, “step ST5”, “ECC decoder outputs”, “ECC decoders 142_1 to 142_4” and “majority circuit 143”, which were mentioned above in connection with the processing performed for four cases (a) to (d), should be read as meaning “step ST14”, “step ST15”, “ECC decoder inputs”, “error detection circuits 144_1 to 144_4” and “majority circuit 145”, respectively.

In case (a), (b) or (c), after step ST15, the majority circuit 145 supplies a selected ECC decoder input and detection result to the error correction circuit 146. In case (d), after step ST15, the majority circuit 145 outputs an error message (a read error) as read data.

The error correction circuit 146 receives the selected ECC decoder input and detection result, and corrects the error included in the ECC decoder input, using the syndrome included in the detection result (ST16). The error correction circuit 146 outputs error-corrected read data (ST17).

The read data output from the error correction circuit 146 or the majority circuit 145 is supplied to a device external to the memory device 1 by way of the input/output circuit 15.

### [2-3] Advantages of Second Embodiment

The second embodiment can produce the same advantages as the first embodiment by performing error detection, selection based on the majority rule and error correction in series. In addition to this, the ECC circuit 14 of the second embodiment requires only one ECC decoder for error correction. Accordingly, the installation area can be reduced.

### [2-4] Modifications of First Embodiment

The second embodiment may be modified in the manner shown in FIG. 18. That is, the ECC circuit 14 may be provided in the memory controller 2.

The first and second embodiments and the modifications thereof are not limited to the examples described above, and can be modified in various ways. In connection with the above-mentioned embodiments, reference was made to the case where the memory device 1 and the memory controller 2 are fabricated as independent semiconductor chips. However, the memory device 1 and the memory controller 2 may be fabricated as one chip.

While certain embodiments have been described, these embodiments have been presented by way of example only, and are not intended to limit the scope. Indeed, the novel embodiments described herein may be embodied in a variety of other forms; furthermore, various omissions, substitutions and changes in the form of the embodiments described herein may be made without departing from the spirit. The accompanying claims and their equivalents are intended to cover such forms or modifications as would fall within the scope and spirit.

What is claimed is:

1. A memory device, comprising:
a plurality of decoders each configured to (i) correct an error and output a corrected read data item if a read data item from a memory circuit corresponding to the decoder contains one error, and (ii) output the read data item if no error is detected in the read data item; and
a majority circuit configured to output a read data item which is the same as one of the read data items of the most read data items output from the plurality of decoders.

2. The memory device of claim 1, wherein the read data item includes no error or includes more than two errors if no error is detected in the read data item.

3. The memory device of claim 1, wherein, when the most read data items output from the plurality of decoders are not existent, the majority circuit selects one of the read data items based on a predetermined condition.

4. The memory device of claim 1, wherein, when the most read data items output from the plurality of decoders are not existent, the majority circuit randomly selects one of the read data items.

5. The memory device of claim 1, wherein the majority circuit outputs a read error if there is no read data item.

6. The memory device of claim 1, wherein, where the read data item includes one error, the decoders correct the error, using a parity and a check matrix.

7. The memory device of claim 1, wherein, where the read data item includes one error, the decoders correct the error, using a parity and a Hamming method.

8. A memory system, comprising:
a plurality of decoders each configured to (i) correct an error and output a corrected read data item if a read data item from a memory circuit corresponding to the decoder contains one error, and (ii) output the read data item if no error is detected in the read data item; and
a majority circuit configured to output a read data item which is the same as one of the read data items of the most read data items output from the plurality of decoders.

9. The memory system of claim 8, wherein the read data item includes no error or includes more than two errors if no error is detected in the read data item.

10. The memory system of claim 8, wherein, when the most read data items output from the plurality of decoders are not existent, the majority circuit selects one of the read data items based on a predetermined condition.

11. The memory system of claim 8, wherein, when the most read data items output from the plurality of decoders are not existent, the majority circuit randomly selects one of the read data items.

12. The memory system of claim 8, wherein the majority circuit outputs a read error if there is no read data item.

13. The memory system of claim 8, wherein, where the read data item includes one error, the decoders correct the error, using a parity and a check matrix.

14. The memory system of claim 8, wherein, where the read data item includes one error, the decoders correct the error, using a parity and a Hamming method.

15. The memory system of claim 8, wherein the memory circuits, the decoders and the majority circuit are fabricated in one semiconductor chip.

16. The memory system of claim 8, wherein the memory circuits are fabricated in one semiconductor chip, and the decoders and the majority circuit are fabricated in a second semiconductor chip different from the first semiconductor chip.

17. A memory device comprising:
a plurality of error detection circuits each configured to perform error detection for read data item read from memory circuits corresponding to the error detection circuit and output a detection result representing whether or not the read data item includes an uncorrectable error;
a majority circuit configured to output a read data item which is the same as one of the read data items of the most read data items output from the error detection circuits; and
an error correction circuit configured to corrects an error and output corrected read data item if read data item read from the memory circuits contains one error, and output the read data item if no error is detected in the read data item.

18. The memory device of claim 17, wherein the read data item that does not include the uncorrectable error is either data item containing no error or data item containing more than two errors.

19. The memory device of claim 17, wherein, when the most read data items output from the plurality of decoders are not existent, the majority circuit selects one of the read data item based on a predetermined condition.

20. The memory device of claim 17, wherein, when the most read data items output from the plurality of decoders are not existent, the majority circuit randomly selects one of the read data item.
